(19) United States
(12) Patent Application Publication
(10) Pub. No.: US 2008/0101425 A1
(43) Pub. Date: May 1, 2008

(54) Electro-absorption semiconductor optical modulator

(75) Inventors: Michio Murata, Yokohama-shi (JP); Haruhisa Soda, Tokyo (JP)

Correspondence Address: SMITH, GAMBRELL & RUSSELL, 1130 CONNECTICUT AVENUE, N.W., SUITE 1130, WASHINGTON, DC, 20036, US

(73) Assignee: SUMITOMO ELECTRIC INDUSTRIES, LTD. and FiBest Limited.

(21) Appl. No.: 11/976,456

(22) Filed: Oct. 24, 2007

(30) Foreign Application Priority Data
Oct. 30, 2006 (JP) P2006-294668

(51) Int. Cl. H01S 5/06; G02F 1/017

(52) U.S. Cl. 372/26; 359/245

(57) ABSTRACT

An electro-absorption semiconductor optical modulator comprises an n-type cladding layer of III-V compound semiconductor; a p-type cladding layer of III-V compound semiconductor; and an active region. The active region is provided between the n-type cladding layer and the p-type cladding layer, and has a quantum well structure. The quantum well structure includes plural semiconductor units, each of which has a well layer, a barrier layer and an interlayer. The interlayer is made of material of a bandgap between a bandgap of the well layer and a bandgap of the barrier layer, and the well layer is compressively strained. The well layer, interlayer and barrier layer are sequentially arranged in each semiconductor unit in a direction from the p-type cladding layer to the n-type cladding layer.

### BACKGROUND OF THE INVENTION

1. Field of the Invention

The present invention relates to an electro-absorption semiconductor optical modulator.

2. Related Background Art

Publication 1 (Japanese Patent Application Laid Open No. 2003-255286) discloses an electro-absorption modulator. This electro-absorption modulator has an interlayer provided between a well layer and a barrier layer, and the interlayer is located on the n-side of the barrier layer, and tensile strain is applied to the well layer. The bandgap Eb (eV) of the barrier layer, the bandgap Ew (eV) of the well layer and the bandgap Em (eV) of the interlayer layer satisfy the following relationship: Ew<E m<Eb. The electro-absorption modulator of a tensile-strained quantum well structure with an interlayer has an extinction ratio equivalent to that of the same as an electro-absorption modulator (comparative example) of a tensile-strained quantum well structure without an interlayer, and has a chirp characteristics lower than that of the comparative example. The electro-absorption modulator in publication 1 reduces the chirping without the deterioration of its extinction ratio. This reduction of the chirping is provided by small positive alpha parameters and negative alpha parameters. Publication 1 discloses that, if an electro-absorption modulator has a tensile-strained quantum well structure, its chirp characteristics is lowered without the deterioration of the extinction ratio thereof.

### SUMMARY OF THE INVENTION

Publication 1 discloses that the application of voltage changes the alpha parameter to a small positive value, and the application of a larger voltage changes the alpha parameter to a large negative value.

Publication 1 discloses that the tensile-strained quantum well structure is a promising structure for low chirping characteristics, and many researcher have thought that low chirping characteristics are easily realized in tensile-strained quantum well structures as compared with compressive-strained quantum well structures. That is, they have thought that alpha parameters in compressive-strained quantum well structures are not changed to small positive and negative large values even if the applied voltage is widely changed.

In order to reduce alpha parameters, the following methods are used: (1) well layers are made shallow with reference to barrier layers; (2) well layers are made thick in thickness; (3) an absorption edge is made close to the wavelength of an input optical signal. In method (1), the extinction ratio is lowered; in method (2), a burden is posed on crystal growth; in method (3), loss to signals of level “1” is increased.

The present invention is made in the circumstances described above, and is obtained through a trial and error process.

It is an object to provide an electro-absorption semiconductor optical modulator that reduces the chirping and avoids the degradation of extinction ratio.

According to one aspect of the present invention, an electro-absorption semiconductor optical modulator comprises an n-type cladding layer of III-V compound semiconductor, a p-type cladding layer of III-V compound semiconductor, and an active region. The active region is provided between the n-type cladding layer and the p-type cladding layer, and has a quantum well structure. The quantum well structure includes plural semiconductor units, each of which has a well layer, a barrier layer and an interlayer. The interlayer is made of material of a bandgap between a bandgap of the well layer and a bandgap of the barrier layer, and the well layer is compressively strained. In each semiconductor unit, the well layer, interlayer and barrier layer are sequentially arranged in a direction from the p-type cladding layer to the n-type cladding layer.

In the electro-absorption semiconductor optical modulator according to the present invention, it is preferable that the quantum well structure be strain-compensated. In the electro-absorption semiconductor optical modulator according to the above case, it is preferable that the interlayer be strain free.

In the electro-absorption semiconductor optical modulator according to the present invention, in a energy band diagram of the quantum well structure, the band edge of light hole of the well layer is located between the band edge of heavy hole of the well layer and the band edge of hole of the interlayer. Further, in the electro-absorption semiconductor optical modulator according to the present invention, the well layer is made of GaInAsP, the barrier layer is made of GaInAsP, and the interlayer is made of GaInAsP.

In the electro-absorption semiconductor optical modulator according to the present invention, the electro-absorption semiconductor optical modulator is integrated with a semiconductor laser; and the electro-absorption semiconductor optical modulator modulates light from the semiconductor laser. Further, in the electro-absorption semiconductor optical modulator according to the present invention, compressive strain is applied to a well layer of the semiconductor laser. Furthermore, in the electro-absorption semiconductor optical modulator according to the present invention, the semiconductor laser has a quantum well structure. The quantum well structure of the semiconductor laser includes plural semiconductor units. Each semiconductor unit of the semiconductor laser has a well layer, a barrier layer and an interlayer. The interlayer is made of material of a bandgap between a bandgap of the well layer and a bandgap of the barrier layer in the semiconductor laser. The well layer is compressively strained in the semiconductor laser, and the well layer, interlayer and barrier layer are sequentially arranged in each semiconductor unit of the semiconductor laser in a direction from the p-type cladding layer to the n-type cladding layer. Additionally, in the electro-absorption semiconductor optical modulator according to the present invention, in the semiconductor laser, the well layer is made of GaInAsP, the barrier layer is made of GaInAsP, and the interlayer is made of GaInAsP.

In the electro-absorption semiconductor optical modulator according to the present invention, the semiconductor laser has a quantum well structure, and the quantum well structure of the semiconductor laser is optically coupled to the quantum well structure of the electro-absorption semiconductor optical modulator semiconductor laser in a butt joint. In the electro-absorption semiconductor optical modulator according to the present invention, the quantum well structure of the semiconductor laser includes well layers and barrier layers alternately arranged. Furthermore, in the electro-absorption semiconductor optical modulator according to the present invention, in the semiconductor laser, each well layer is made of GaInAsP, and each barrier layer is made of GaInAsP.

In the electro-absorption semiconductor optical modulator according to the present invention, the interlayer is located on an n-side of the well layer in each semiconductor unit, and the n-side of the well layer is directed to the n-type cladding layer. Further, in the electro-absorption semiconductor optical modulator according to the present invention, the interlayer in one of the semiconductor units is located between the well layer in the one of the semiconductor units and the barrier layer in another of the semiconductor units. The one of the semiconductor units and the other of the semiconductor units are adjacent to each other, and the one of the semiconductor units is provided between the p-type cladding layer and the other of the semiconductor units.

In the electro-absorption semiconductor optical modulator according to the present invention, the barrier layer is located on a p-side of the well layer in each semiconductor unit. The p-side of the well layer is directed to the p-type cladding layer, and the well layer is located between the barrier layer and the interlayer in each semiconductor unit. Further, in the electro-absorption semiconductor optical modulator according to the present invention, the barrier layer in one of the semiconductor units is located between the well layer in the one of the semiconductor units and the interlayer in another of the semiconductor units, the one of the semiconductor units and the other of the semiconductor units are adjacent to each other, and the one of the semiconductor units is provided between the n-type cladding layer and the other of the semiconductor units.

In the electro-absorption semiconductor optical modulator according to the present invention, a wave function of electron in a conduction band in the well layer is deformed to spread in the well layer and interlayer in response to a reverse voltage applied to the active region. Further, in the electro-absorption semiconductor optical modulator according to the present invention, a wave function of heavy hole in a valence band in the well layer is deformed to localize in the well layer in response to the reverse voltage.

In the electro-absorption semiconductor optical modulator according to the present invention, the plural semiconductor units are arranged in a direction from the p-type cladding layer to the n-type cladding layer. Further, in the electro-absorption semiconductor optical modulator according to the present invention, the barrier layer has tensile strain and the interlayer is strain free.

### BRIEF DESCRIPTION OF THE DRAWINGS

The above objects and other objects, features, and advantages of the present invention will be understood easily from the following detailed description of the preferred embodiments of the present invention with reference to the accompanying drawings.

FIG. 1 is a schematic view showing the structure of an electro-absorption semiconductor optical modulator according to the present embodiment;

FIG. 2 is a diagram showing the bandgap and the wave functions of election, heavy hole and light hole;

FIG. 3 is a view showing the waveform of a signal modulated by the electro-absorption semiconductor optical modulator in FIG. 1 and the waveform of a signal after 100 kilometer transmission of the modulated signal;

FIG. 4 is a view showing the waveform “S” of the modulated signal and the waveform “C” indicating the degree of chirping;

FIG. 5 is a view showing the relationship between absorption coefficients and alpha parameters in well layers of the compressive stress of 0, 0.25, 0.5 and 0.75 in percentage terms;

FIG. 6 is a view showing the relationship between absorption coefficients and alpha parameters in well layers of the thickness of 0, 1, 2 and 3 in nanometers;

FIG. 7 is a view showing a semiconductor optical device into which an electro-absorption semiconductor modulator and a semiconductor laser are integrated;

FIG. 8 is a view of major steps of fabricating a semiconductor optical device including an electro-absorption semiconductor modulator and a semiconductor laser;

FIG. 9 is a view of major steps of fabricating the semiconductor optical device including the electro-absorption semiconductor modulator and the semiconductor laser; and

FIG. 10 is a view of major steps of fabricating the semiconductor optical device including the electro-absorption semiconductor modulator and the semiconductor laser.

### DETAILED DESCRIPTION OF THE PREFERRED EMBODIMENTS

Referring to the accompanying drawings, embodiments of the present invention will be explained. When possible, parts identical to each other will be referred to with symbols identical to each other.

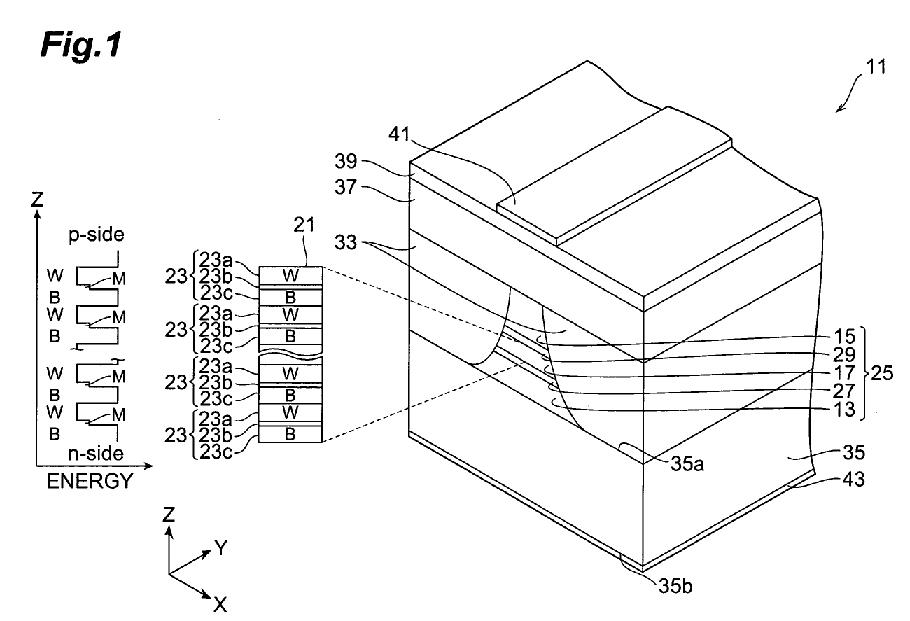

FIG. 1 is a schematic view showing the structure of an electro-absorption semiconductor optical modulator according to a present embodiment. The electro-absorption semiconductor optical modulator modulates light of a predetermined wavelength component in response to an electrical signal applied thereto. The electro-absorption semiconductor optical modulator 11 comprises an n-type cladding layer 13, a p-type cladding layer 15, and an active region 17. The active region 17 is provided between the n-type cladding layer 13 and the p-type cladding layer 15. Each of the n-type cladding layer 13 and p-type cladding layer 15 is made of III-V compound semiconductor. The active region 17 has a quantum well structure 21, and this quantum well structure 21 includes semiconductor laminates, each of which is referred to as a semiconductor unit 23. The semiconductor unit 23 includes a well layer 23a (referred to as “W” in FIG. 1), an interlayer 23b (referred to as “M” in FIG. 1) and a barrier layer 23c (referred to as “B” in FIG. 1). Each of the well layer 23a, interlayer 23b and barrier layer 23c is made of III-V compound semiconductor. The semiconductor material of the interlayer 23b has a bandgap “E_{M}” between the bandgap “E_{B}” of the barrier layer 23c and the bandgap “E_{W}” of the well layer 23a. In the semiconductor unit 23, the well layer 23a, interlayer 23b and barrier layer 23c are sequentially arranged in the direction from the p-type cladding layer to the n-type cladding layer. The well layer 23a is compressively strained.

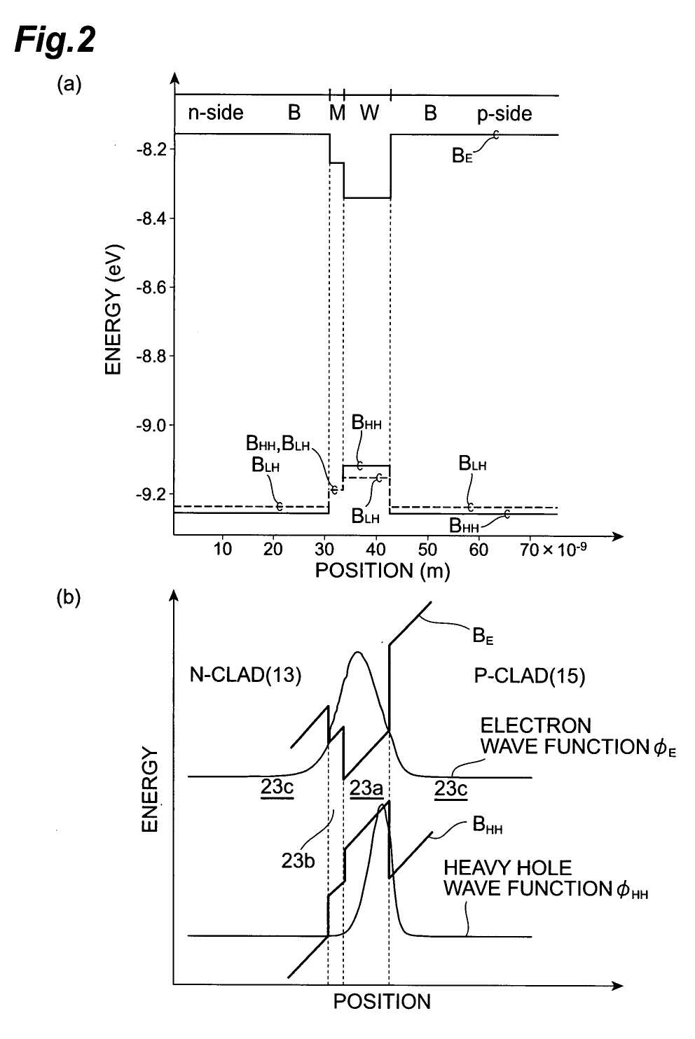

Part (a) of FIG. 2 shows a zero biasing band diagram of light hole, heavy hole and electron. The axis of abscissas indicates position in meters, and the axis of ordinate indicates energy in electron volts (1 eV=1.602×10⁻¹⁹ Joule). Symbol “B_{E}” indicates an electron band (conduction band), symbol “B_{HH}” indicates a heavy hole band, and symbol “B_{LH}” indicates a light hole band. Since compressive strain is applied to the well layer 23a, the heavy hole band is located in the bottom of the valence band. Hence, in the axis of abscissas, the energy of heavy hole band “B_{HH}” is greater than that of light hole band “B_{LH}.” The major interaction occurs between holes in heavy hole band “B_{HH}” and electrons in the conduction band. In the electro-absorption semiconductor optical modulator 11, the edge of light hole band “B_{LH}” in the well layer 23a is located between the edge of light hole band “B_{HH}” in the well layer 23a and the edge of hole band “B_{H}” (B_{HH}=B_{HL}) in the interlayer 23b. The active region 17 includes plural units 23 arranged in the direction of z-axis.

In the electro-absorption semiconductor optical modulator 11, negative voltage is applied to anode electrode and positive voltage is applied to cathode electrode. Thus, the pn junction in the electro-absorption semiconductor optical modulator 11 is reversely biased. Part (b) of FIG. 2 shows the band diagram and the shapes of wave functions of electron and heavy hole in a reverse biasing condition.

The well layer 23a, interlayer 23b and barrier layer 23c are arranged as above in the electro-absorption semiconductor optical modulator 11, that is, the interlayer 23b is provided on the n-side, which is directed to the n-type cladding layer, of the well layer 23a. Thus, the confinement of the wave function of electron in the conduction band into the well layer 23a is weakened in applying a reverse bias, and the peak of the wave function φ_{E} is shifted toward the interlayer 23b. Hence, the wave function φ_{E} is broadened in the well layer 23a and the interlayer 23b to reduce the peak value of the wave function φ_{E}. In contrast, since the interlayer 23b is not provided on the other side, which is directed to the p-type cladding layer, of the well layer 23a, the wave function φ_{HH} is shifted by moving the heavy holes in response to a reverse bias in a direction opposite to the moving direction of electron in the conduction band. Accordingly, the wave function φ_{HH} is localized and the peak value of the wave function φ_{HH} is not decreased. Consequently, the overlap of the wave functions φ_{E} and φ_{HH} is decreased as a whole to reduce the absorption of the incident light in a short wavelength region. Therefore, the alpha parameter is made negative, and the chirping characteristics become excellent. If the well layer 23a is compressively strained, the alpha parameter is shifted to a negative value.

Referring again to FIG. 1, a semiconductor mesa 25 of the electro-absorption semiconductor optical modulator 11 includes the n-type cladding layer 13, the p-type cladding layer 15 and the active region 17. A first optical guide layer 27 is provided between the n-type cladding layer 13 and the active region 17, and a second optical guide layer 29 is provided between the p-type cladding layer 15 and the active region 17. Each of the first and second optical guide layer 27, 29 is made of III-V compound semiconductor. The semiconductor mesa 25 is buried by a burying region 33, and a reverse bias voltage between a cathode electrode and an anode electrode is effectively applied to the active region 17. The semiconductor mesa 25 and the burying region 33 are provided on the primary surface 35a of the semiconductor substrate 35. A cladding layer 37 is provided on the semiconductor mesa 25 and the burying region 33, and a contact layer 39 is provided the cladding layer 37. A first electrode 41 is provided on the contact layer 39, and a second electrode 43 is provided on the back side 35b of the substrate 35. Each of the cladding layer 37 and contact layer 39 is made of III-V compound semiconductor.

In the electro-absorption semiconductor optical modulator 11 shown in FIG. 1, the semiconductor substrate 35 has n-type conductivity, and the cladding layer 37 and contact layer 39 have p-type conductivity, but the conductive type of the substrate is not limited to the above. P-type substrates can be used in place of the n-type conductivity substrate, and a cladding layer and contact layer of n-type conductivity can be used in place of the cladding layer 37 and contact layer 39 of p-type conductivity.

It is preferable that the quantum well structure 21 be strain-compensated. In the electro-absorption semiconductor optical modulator 11 that is strain-compensated, the well layers have compressive strains and this strain-compensation permits the crystal quality of the active region to become excellent. The quantum well structure 21 shown in Part (a) of FIG. 2 is strain-compensated. Since the barrier layers 23c are tensile-strained for the above strain compensation, the band of light hole is located in the bottom of the valence band in the barrier layers 23c. Therefore, the band “B_{LH}” of light hole is greater than the band “B_{HH}” of heavy hole.

It is preferable that the interlayer 23b be strain-free. Accordingly, the strain relation of the quantum well structure does not become complicated, and rather simple. The band structure 21 shown in Part (a) of FIG. 2 has a strain-free interlayer. In the interlayer 23b, the band “B_{HH}” of heavy hole and the band “B_{LH}” of light hole are degenerate.

In one example of the electro-absorption semiconductor optical modulator 11, the well layer 23a is made of GaInAsP, the barrier layer is made of GaInAsP, and the interlayer is made of GaInAsP. According to the above example of the electro-absorption semiconductor optical modulator 11, it is easy to obtain both the relation of strains and the relation of bandgaps by changing the compositions of the well layer, interlayer and barrier layer.

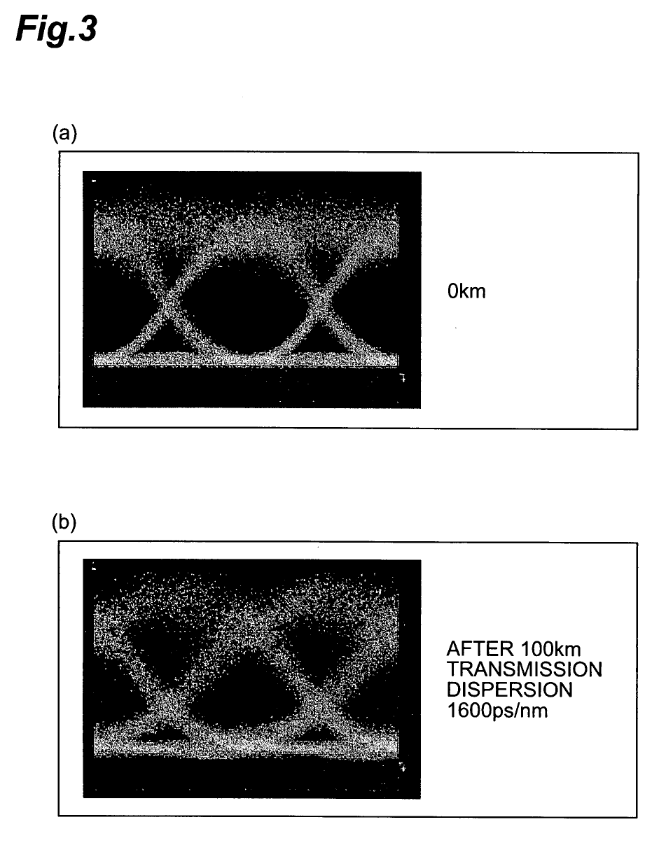

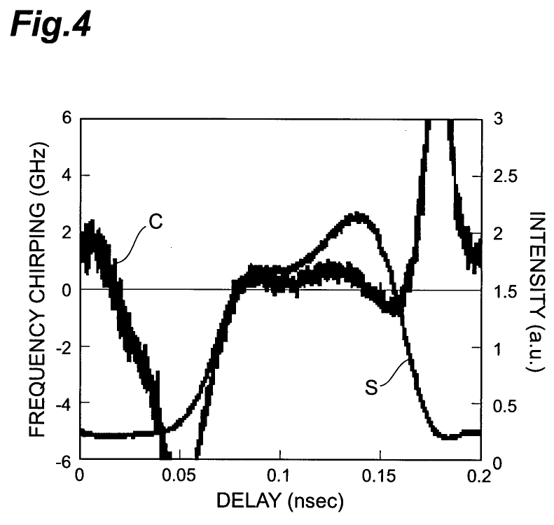

Part (a) of FIG. 3 shows a signal waveform modulated by the electro-absorption semiconductor optical modulator 11 shown in FIG. 1, and this signal wave form was measured just after the electro-absorption semiconductor optical modulator 11, i.e, the transmission distance is zero kilometer. Part (b) of FIG. 3 shows a signal waveform after 100-kilometer transmission of the modulated optical signal. The dispersion of this transmission line is 1600 ps/nm. When these waveforms in Parts (a) and (b) of FIG. 3 are compared to each other, the optical signal after 100-kilometer transmission shows an excellent eye pattern. FIG. 4 shows intensity waveform “S” of the modulated signal and chirp waveform “C” indicating chirp quantity. The chirp waveform “C” indicates that the modulated signal has a negative chirp at the rising edge of the intensity waveform “S” and that the modulated signal has a positive chirp at the falling edge of the intensity waveform “S.”

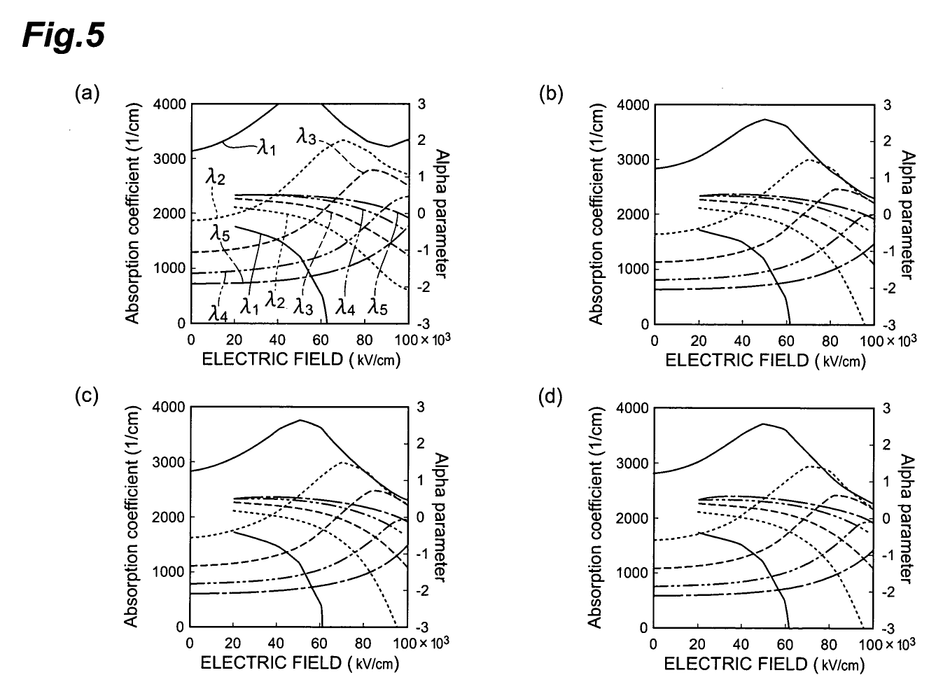

Parts (a) to (d) of FIG. 5 show relationships between alpha parameters and absorption coefficients in the well layers to which compressive stains of 0%, 0.25%, 0.5% and 0.75% are applied. These relationships are obtained by calculating alpha parameters of a double quantum well structure including interlayer. The axis of abscissas indicates electrical field strength. The left axis of abscissas indicates absorption coefficient, and the right axis of abscissas indicates alpha parameter. In each part of FIG. 5, curves of absorption coefficient and alpha parameter labeled by 100-nanometer-step wavelength components (λ₁, λ₂, λ₃, λ₄, λ₅) are calculated in the wavelength range of 1570 nm to 1530 nm. These curves reveal that alpha parameters tend to be negative by applying compressive strain to the well layers. It is preferable that the quantity of the strain to the well layers be equal to or less than 1%, for example. Compressive strain to the well layers greater than 1% degrades the crystal quality, and FIG. 5 shows that it is preferable that compressive strain to the well layers be not less than 0.25%, for example.

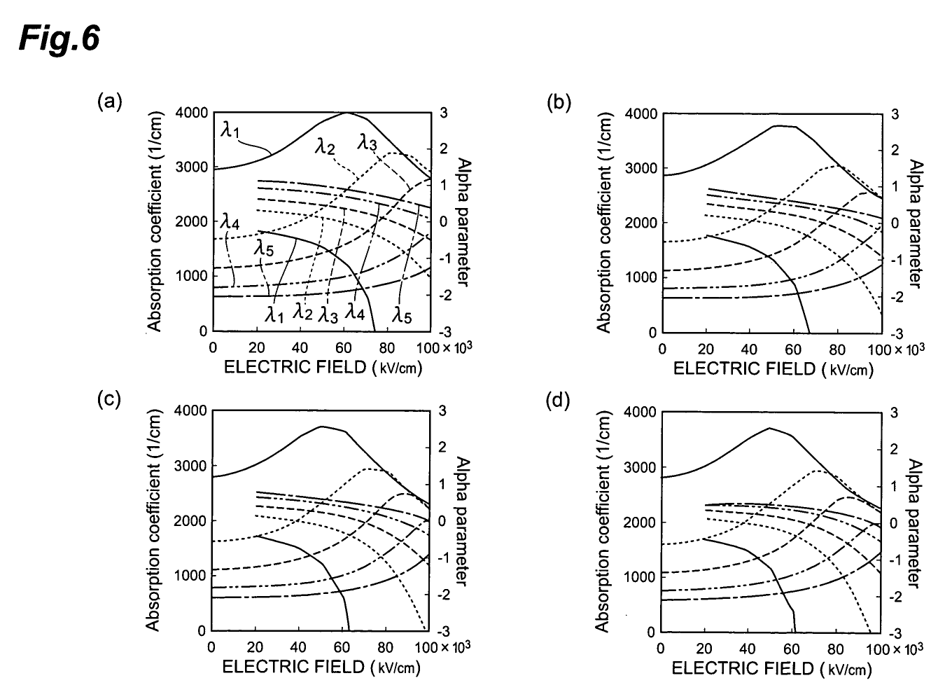

Parts (a) to (d) of FIG. 6 show relationships between alpha parameters and absorption coefficients in plural interlayers which have the thickness of 0 nm, 1 nm, 2 nm and 3 nm. These relationships are obtained by calculating alpha parameters of a double quantum well structure including the interlayer. The axis of abscissas indicates electrical field strength. The left axis of abscissas indicates absorption coefficient, and the right axis of abscissas indicates alpha parameter. In each part of FIG. 6, curves of absorption coefficient and alpha parameter labeled by 100-nanometer-step wavelength components (λ₁, λ₂, λ₃, λ₄, λ₅) are calculated in the wavelength range of 1570 nm to 1530 nm. These curves reveal that alpha parameters tend to be negative by providing the interlayer on the n-side, which is oriented to the n-type cladding layer, of the well layer. This tendency can be easily understood from the comparison of alpha parameter at the electric field strength of 80 kV/cm in the characteristic curve of λ=1.65 micrometers. It is preferable that the thickness of the interlayer be equal to or less than 4 nm, for example. The thickness of the well layer greater than 4 nm prevents the absorption of light in the well layer, and FIG. 6 shows that it is preferable that the thickness of the well layers be not less than 2 nm, for example.

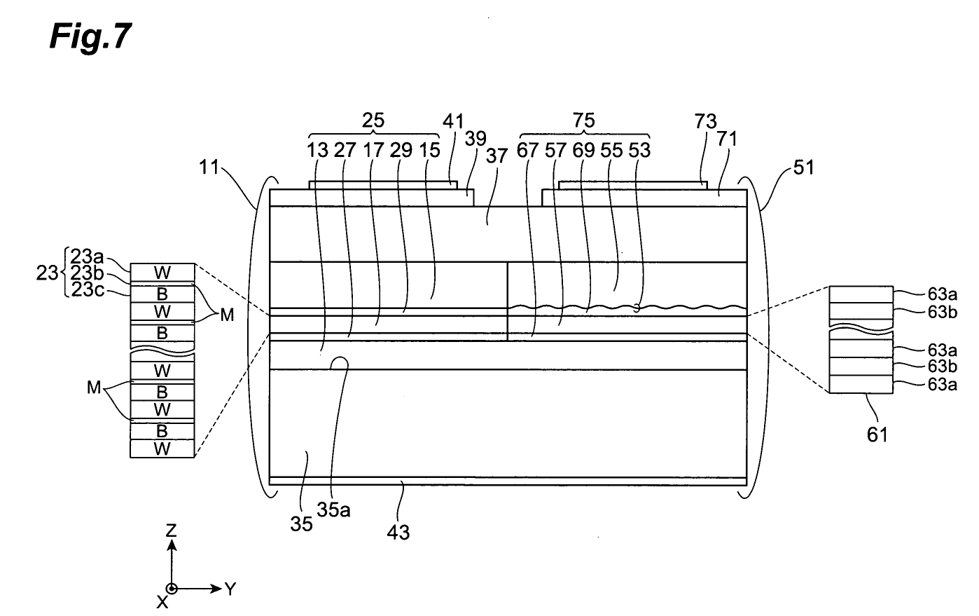

FIG. 7 is a view showing a semiconductor optical device into which an electro-absorption semiconductor optical modulator and a semiconductor laser are integrated. The electro-absorption semiconductor optical modulator 11 according to the present embodiment is fabricated as a single component, and has a structure favorable to the integration with a semiconductor laser 51 to form semiconductor optical device. One example of the semiconductor laser 51 is a distributed feedback (DFB) semiconductor laser. The semiconductor laser 51 includes the n-type cladding layer 13, a diffraction grating 53, a p-type cladding layer 55, and an active region 57. The active region 57 is provided between the n-type cladding layer 13 and p-type cladding layer 55. The p-type cladding layer 55 is made of III-V compound semiconductor. The active region 57 has a quantum well structure, and this quantum well structure 61 has well layers 63a and barrier layers 63b. Each of the well layers 63a and barrier layers 63b is made of III-V compound semiconductor. A laser beam is generated in response to the application of positive and negative voltages to the anode electrode and the cathode electrode, respectively, and the electro-absorption semiconductor optical modulator 11 modulates the laser beam from the semiconductor laser 51.

In the semiconductor laser 51, a semiconductor mesa 75 includes the n-type cladding layer 13, p-type cladding layer 55 and the active region 57. A third optical guide layer 67 is provided between the n-type cladding layer 13 and the active region 57, and fourth optical guide layer 69 is provided between the p-type cladding layer 55 and the active region 57. The semiconductor mesa 75 is buried by a burying region 33, electrical current flowing from the anode electrode to the cathode electrode is effectively confined into the active region 57. The semiconductor mesa 75 and the burying region 33 are provided on the primary surface 35a of the semiconductor substrate 35. The cladding layer 37 is provided on the semiconductor mesa 75 and the burying region 33. A contact layer 71 is provided on the cladding layer 37. The contact layer 71 is made of the same material of the contact layer 39, and is isolated from the contact layer 39. A third electrode 73 is provided on the contact layer 71, and the second electrode 43 on the back side 35b of the semiconductor substrate 35 is shared with the electro-absorption semiconductor optical modulator 11.

In the semiconductor laser 51, the semiconductor substrate 35 has n-type conductivity as in the electro-absorption semiconductor optical modulator 11, and the contact layer 71 has p-type conductivity. But, the present invention is not limited thereto, p-type semiconductor substrates can be used in place of the semiconductor substrate 35 of n-type conductivity, and n-type cladding and contact layers can be used in place of the cladding and contact layers of p-type conductivity.

One example of the electro-absorption semiconductor optical modulator 11 is as follows:

semiconductor substrate 35: n-type InP;
n-type cladding region 13: n-type InP;
p-type cladding region 15: p-type InP;
active region 17 (multiple quantum well structure)
well layer 23a: InGaAsP (its bandgap wavelength is adjusted such that photo luminescence wavelength is 1.52 micrometers)
6 nm, compressive strain 0.8%;
   interlayer 23b: InGaAsP (its bandgap wavelength is 1.3 micrometers)
3 nm, strain free;
   barrier layer 23c: InGaAsP (its bandgap wavelength is 1.15 micrometers)
10 nm, tensile strain 0.3%;
   first optical guide layer 27: InGaAsP (its bandgap wavelength is 1.15 micrometers)
   second optical guide layer 29: InGaAsP (its bandgap wavelength is 1.15 micrometers)
   burying region 33: for example, n-type InP and p-type InP;
   cladding layer 37: p-type InP, 2-micrometer thick;
   contact layer 39: p-type GaInAs, 200-nanometer thick;
   first electrode: anode; and
   second electrode: cathode.

One example of the semiconductor laser 51 is as follows:

n-type cladding region 13: n-type InP;
p-type cladding region 55: p-type InP;
active region 57 (multiple quantum well structure)
well layer 63a: InGaAsP (bandgap wavelength is adjusted such that photo luminescence wavelength is 1.56 micrometers)
5 nm thick;
   barrier layer 63b: InGaAsP (bandgap wavelength is 1.2 micrometers)
10 nm thick;
   third optical guide layer 67: InGaAsP (bandgap wavelength is 1.15 micrometers);
   fourth optical guide layer 69: InGaAsP (bandgap wavelength is 1.15 micrometers);
   cladding layer 37: p-type InP, 2-micrometer thick;
   contact layer 71: p-type GaInAs, 200-nanometer thick;
   third electrode 73: anode; and
   fourth electrode 43: cathode.

The quantum well structure 21 of the semiconductor mesa 25 and the quantum well structure 61 of the semiconductor mesa 75 can be fabricated by selective growth using a dielectric mask. Alternatively, the semiconductor mesa 25 and the semiconductor mesa 75 are fabricated by butt-joint method.

It is preferable that the well layers 63a in the semiconductor laser 51 be compressively strained. In this the electro-absorption semiconductor optical modulator, the well layers 63a of the semiconductor laser 51 can be made by selectively growth method in the same steps as the growth of the well layers 13a. It is preferable that the quantum well structure 61 be strain-compensated, and the strain-compensation is made crystal quality of semiconductor layers for the semiconductor laser excellent. When the well layers 63a of the semiconductor laser 51 are made by selectively growth method in the same steps as the growth of the well layers 13a, the barrier layers 63b of the semiconductor laser 51 are made by selectively growth method in the same steps as the growth of the barrier layers 13c. The quantum well structure 61 also includes the interlayer.

When the semiconductor mesa 25 and semiconductor mesa 75 are fabricated by butt-joint method, the strain of the well layers 63a in the semiconductor laser 51 is not restricted by the strain of the well layers 23a in the electro-absorption semiconductor optical modulator 11.

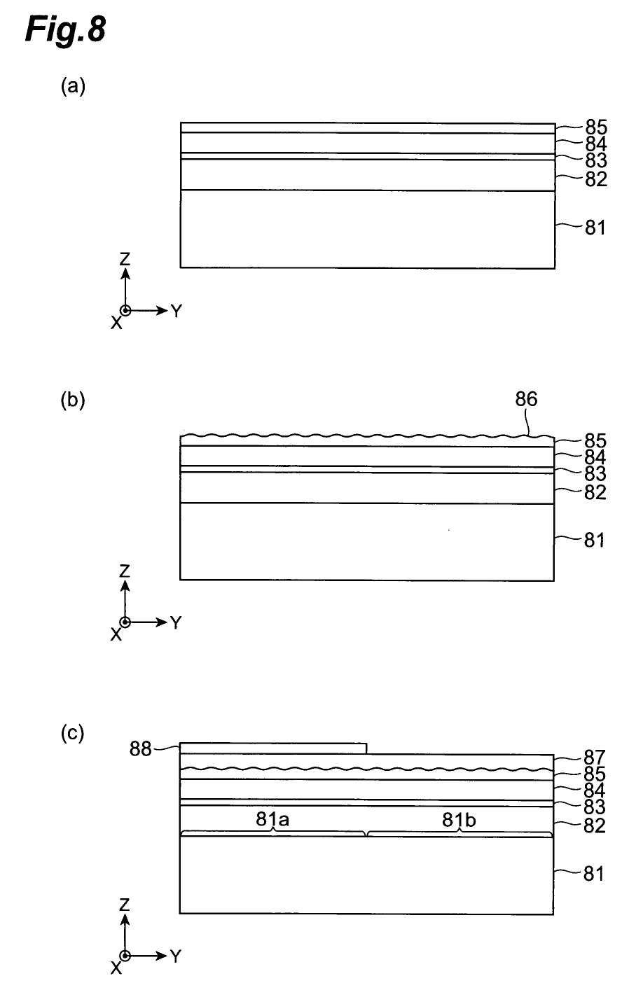

With reference to FIGS. 8, 9 and 10, the major steps in fabricating the electro-absorption semiconductor optical modulator 11 and semiconductor laser 51 will be explained as follows. As shown in Part (a) of FIG. 8, layered semiconductors are deposited on a semiconductor substrate 81 of n-type InP by MOVEP method to form an n-type InP cladding layer 82, an GaInAsP optical guide layer 83, a quantum well structure 84, and an GaInAsP optical guide layer 85 on the semiconductor substrate 81. The quantum well structure 84 includes a well layer of GaInAsP and a barrier layer of GaInAsP. Then, as shown in Part (a) of FIG. 8, a periodic structure 86 for a DFB diffraction grating is formed on the surface of the GaInAsP optical guide layer 85 by use of a dielectric mask.

As shown in Part (c) of FIG. 8, after forming the periodic structure 86, a p-type cladding layer 87 is formed thereon. After forming the p-type cladding layer 87, a dielectric mask 88 of, for example, silicon oxide is formed on the first area 81a of the semiconductor substrate 81.

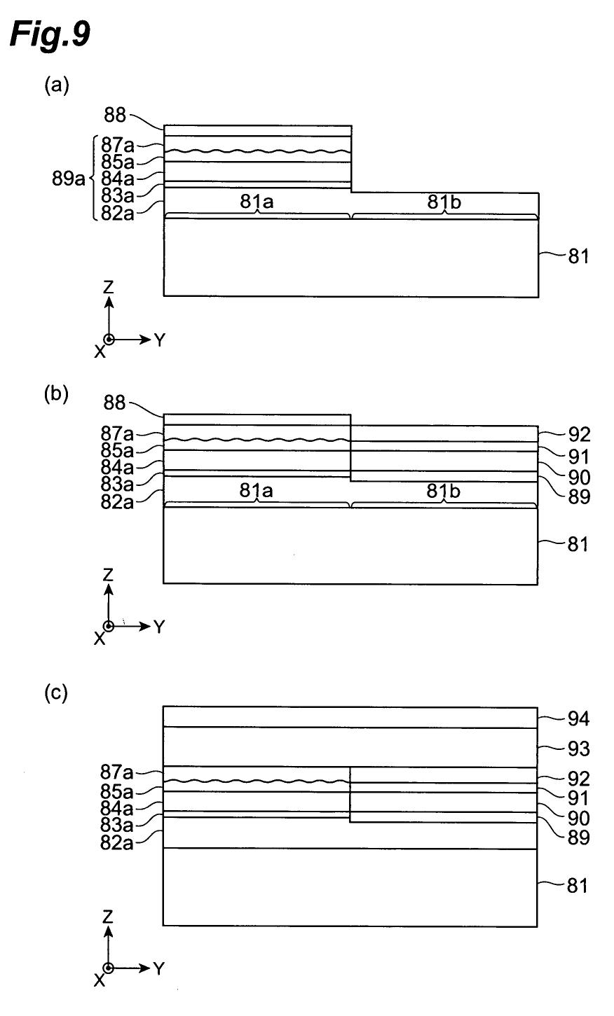

As shown in Part (a) of FIG. 9, layered semiconductors 89a for the semiconductor laser 51 are formed. The n-type InP cladding layer 82, GaInAsP optical guide layer 83, quantum well structure 84, GaInAsP optical guide layer 85 and p-type cladding layer 87 are etched using the dielectric mask to form an n-type InP cladding layer 82a, GaInAsP optical guide layer 83a, quantum well structure 84a, GaInAsP optical guide layer 85a and the p-type cladding layer 87a. This etching is carried out by reactive ion etching (RIE) method.

As shown in Part (b) of FIG. 9, a GaInAsP optical guide layer 89, quantum well structure 90, a GaInAsP optical guide layer 91 and p-type InP cladding layer 92 are sequentially grown on the second area 81b of the semiconductor substrate 81 by MOVPE method by use of the dielectric mask 88. Thereafter, the dielectric mask 88 is removed.

After removing the dielectric mask 88, as shown in Part (c) of FIG. 9, a p-type InP cladding layer 93 and p-type GaInAs contact layer 94 are sequentially grown on the first and second areas 81a and 81b of the substrate 81 by MOVPE method.

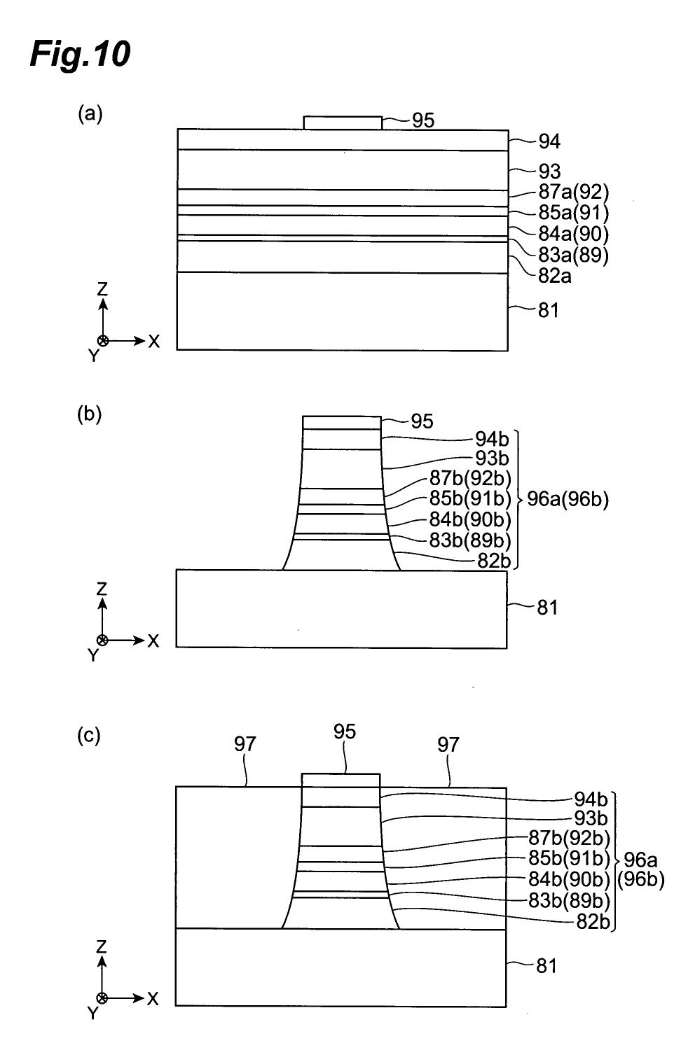

As shown in Part (a) of FIG. 10, a dielectric mask 95 for forming a semiconductor mesa is formed. As shown in Part (b) of FIG. 10, the layered semiconductors are etched using the dielectric mask 95 to form a semiconductor mesa 96a for the electro-absorption semiconductor optical modulator 11 and a semiconductor mesa 96b for the semiconductor laser 51. The semiconductor mesa 96a includes an n-type InP cladding layer 82b, a GaInAsP optical guide layer 83b, a quantum well structure 84b, a GaInAsP optical guide layer 85b, a p-type InP cladding layer 87b, a p-type cladding layer 93b and a p-type GaInAs contact layer 94b. The semiconductor mesa 96b includes the n-type InP cladding layer 82b, a GaInAsP optical guide layer 89b, a quantum well structure 90b, a GaInAsP optical guide layer 91b, a p-type InP cladding layer 92b, the p-type cladding layer 93b and the p-type GaInAs contact layer 94b. Parenthetical reference symbols in Part (a) to (c) of FIG. 10 indicate components belonging to the semiconductor mesa 96b, which are not shown in FIG. 10 because the semiconductor mesa 96a hides them.

As shown in Part (c) of FIG. 10, an InP semiconductor 97 is deposited using the dielectric mask 95 to cover the sides of the semiconductor mesa 96a for the electro-absorption semiconductor optical modulator 11 and the semiconductor mesa 96b for the semiconductor laser 51. The semiconductor mesa 96a and semiconductor mesa 96b are buried by the InP burying semiconductor layer 97. After this burying, anode and cathode electrodes are formed. The semiconductor optical device has been fabricated after the above steps.

The fabrication of the quantum well structures for the electro-absorption semiconductor optical modulator 11 and semiconductor laser 51 is not limited to the butt-joint method as described above, and selective growth method can be used as well. In this selective growth method, an active layer for the electro-absorption semiconductor optical modulator 11 is formed at the same time as the active layer for the semiconductor laser 51. The selective growth method can be performed using a mask for selective growth by MOVPE method. The primary surface of the substrate has the first area for forming the active layer of the DFB semiconductor laser (DFB laser portion) and the second area for forming the active layer of the optical modulator (modulator portion). The mask for selective growth has a first opening (slit) located on the first area, and the second area is not covered with the mask. If required, the mask for selective growth has a second opening (slit) located on the second area, and the second opening is wider than the first opening. In the modulator portion which is not covered with the mask, inherent semiconductor as designed is deposited. Since the mask on the DFB laser portion has the slit and this slit increases growth rate, a semiconductor layer which is formed using the mask is thicker than a semiconductor layer in the modulator portion and has a composition different from the semiconductor layer in the modulator portion. These differences are adjusted by the size of the slit (mask ratio). When the mask ratio is high, the growth rate is increased and the well layer becomes thick in thickness. The increase of the well layer in thickness shifts a peak of the photo luminescence spectrum in the multiple quantum well (MQW) structure to a longer wavelength region. The ratio of Indium to Gallium in the composition of GaInAsP becomes greater, and the wavelength of the MQW structure is also shifted to a longer wavelength region. The well layers in the semiconductor laser are compressively strained. It is preferable that a selectively-growing mask having a width be used so that the peak wavelength of the photoluminescence spectrum from the MQW structure of the semiconductor laser is longer than the peak wavelength of the photoluminescence spectrum from the MQW structure of the modulator portion by 40 nanometers. Thereafter, a semiconductor laser integrated with a modulator as in the above embodiment is fabricated.

In this method, the multiple quantum well structure in the semiconductor laser includes the interlayer directly located on the n-side of the well layer. In this MQW, since the barrier layer is directly located on the p-side of the well layer and it is important that electrons of a effective mass smaller than that of holes is confined to the well layers, the performance of the modulator can be improved by use of the simple fabrication process as above without the degradation of the performance of the carrier confinement.

Having described and illustrated the principle of the invention in a preferred embodiment thereof, it is appreciated by those having skill in the art that the invention can be modified in arrangement and detail without departing from such principles. We therefore claim all modifications and variations coming within the spirit and scope of the following claims.

What is claimed is:

1. An electro-absorption semiconductor optical modulator comprising:
an n-type cladding layer of III-V compound semiconductor;
a p-type cladding layer of III-V compound semiconductor; and
an active region, the active region being provided between the n-type cladding layer and the p-type cladding layer, the active region having a quantum well structure, the quantum well structure including plural semiconductor units, each semiconductor unit having a well layer, a barrier layer and an interlayer, the interlayer being made of material of a bandgap between a bandgap of the well layer and a bandgap of the barrier layer, the well layer being compressively strained, and the well layer, interlayer and barrier layer being sequentially arranged in each semiconductor unit in a direction from the p-type cladding layer to the n-type cladding layer.

2. The electro-absorption semiconductor optical modulator according to claim 1, wherein the quantum well structure is strain-compensated.

3. The electro-absorption semiconductor optical modulator according to claim 2, wherein the interlayer is strain free.

4. The electro-absorption semiconductor optical modulator according to according to claim 1, wherein, in a energy band diagram of the quantum well structure, a band edge of light hole of the well layer is located between a band edge of heavy hole of the well layer and a band edge of hole of the interlayer.

5. The electro-absorption semiconductor optical modulator according to claim 1, wherein the well layer is made of GaInAsP, the barrier layer is made of GaInAsP, and the interlayer is made of GaInAsP.

6. The electro-absorption semiconductor optical modulator according to claim 1, wherein the electro-absorption semiconductor optical modulator is integrated with a semiconductor laser, and the electro-absorption semiconductor optical modulator modulates light from the semiconductor laser.

7. The electro-absorption semiconductor optical modulator according to claim 6, wherein a compressive strain is applied to a well layer of the semiconductor laser.

8. The electro-absorption semiconductor optical modulator according to claim 6, wherein the semiconductor laser has a quantum well structure, the quantum well structure of the semiconductor laser includes plural semiconductor units, each semiconductor unit of the semiconductor laser has a well layer, a barrier layer and an interlayer, the interlayer is made of material of a bandgap between a bandgap of the well layer and a bandgap of the barrier layer in the semiconductor laser, the well layer is compressively strained in the semiconductor laser, and the well layer, interlayer and barrier layer are sequentially arranged in each semiconductor unit of the semiconductor laser in the direction from the p-type cladding layer to the n-type cladding layer.

9. The electro-absorption semiconductor optical modulator according to claim 8, wherein, in the semiconductor laser, the well layer is made of GaInAsP, the barrier layer is made of GaInAsP, and the interlayer is made of GaInAsP.

10. The electro-absorption semiconductor optical modulator according to claim 6, wherein the semiconductor laser has a quantum well structure, and the quantum well structure of the semiconductor laser is optically coupled to the quantum well structure of the electro-absorption semiconductor optical modulator semiconductor laser in a butt joint.

11. The electro-absorption semiconductor optical modulator according to claim 10, wherein the quantum well structure of the semiconductor laser includes well layers and barrier layers alternately arranged.

12. The electro-absorption semiconductor optical modulator according to claim 11, wherein, in the semiconductor laser, each well layer is made of GaInAsP, and each barrier layer is made of GaInAsP.

13. The electro-absorption semiconductor optical modulator according to claim 1, wherein the interlayer is located on an n-side of the well layer in each semiconductor unit, and the n-side of the well layer is directed to the n-type cladding layer.

14. The electro-absorption semiconductor optical modulator according to claim 13, wherein the interlayer in one of the semiconductor units is located between the well layer in the one of the semiconductor units and the barrier layer in another of the semiconductor units, the one of the semiconductor units and the other of the semiconductor units are adjacent to each other, and the one of the semiconductor units is provided between the p-type cladding layer and the other of the semiconductor units.

15. The electro-absorption semiconductor optical modulator according to claim 1, wherein the barrier layer is located on a p-side of the well layer in each semiconductor unit, the p-side of the well layer is directed to the p-type cladding layer, and the well layer is located between the barrier layer and the interlayer in each semiconductor unit.

16. The electro-absorption semiconductor optical modulator according to claim 15, wherein the barrier layer in one of the semiconductor units is located between the well layer in the one of the semiconductor units and the interlayer in another of the semiconductor units, the one of the semiconductor units and the other of the semiconductor units are adjacent to each other, and the one of the semiconductor units is provided between the n-type cladding layer and the other of the semiconductor units.

17. The electro-absorption semiconductor optical modulator according to claim 1, wherein the plural semiconductor units are arranged in the direction from the p-type cladding layer to the n-type cladding layer.

18. The electro-absorption semiconductor optical modulator according to claim 1, wherein the barrier layer has tensile strain and the interlayer is strain free.
